(19) United States
(12) Patent Application Publication
(10) Pub. No.: US 2014/0339566 A1
(43) Pub. Date: Nov. 20, 2014

(54) SEMICONDUCTOR DEVICE AND METHOD OF FABRICATING THE SAME

(71) Applicant: Seoul Viosys Co., Ltd., Ansan-si (KR)

(72) Inventors: Won Cheol Seo, Ansan-si (KR); Dae Sung Cho, Ansan-si (KR); Chung Hoon Lee, Ansan-si (KR); Ki Bum Nam, Ansan-si (KR)

(21) Appl. No.: 14/364,281

(22) PCT Filed: Dec. 13, 2012
(86) PCT No.: PCT/KR2012/010852

§ 371 Date: Jun. 10, 2014

(30) Foreign Application Priority Data
Dec. 14, 2011 (KR) 10-2011-0134130
Dec. 15, 2011 (KR) 10-2011-0135513
Mar. 16, 2012 (KR) 10-2012-0026879
Mar. 16, 2012 (KR) 10-2012-0026948

(51) Int. Cl. H01L 33/32; H01L 33/00; H01L 33/42; H01L 33/38; H01L 33/22

(52) U.S. Cl. CPC H01L 33/32; H01L 33/38; H01L 33/22; H01L 33/42; H01L 33/0075
USPC 257/76; 438/46

(57) ABSTRACT

Disclosed are a semiconductor device and a method of fabricating the same. The method includes forming a first GaN layer, a sacrificial layer and a second GaN layer on a GaN substrate, wherein the sacrificial layer has a bandgap narrower than those of the GaN layers; forming a groove penetrating the second GaN layer and the sacrificial layer; growing GaN-based semiconductor layers on the second GaN layer to form a semiconductor stack; forming a support substrate on the semiconductor stack; and removing the GaN substrate from the semiconductor stack by etching the sacrificial layer. Accordingly, since the sacrificial layer is etched using the groove, the support substrate can be separated from the semiconductor stack without damaging the support substrate.

### CROSS-REFERENCE TO RELATED APPLICATIONS

This application is the National Stage of International Application No. PCT/KR2012/010852, filed on Dec. 13, 2012, and claims priority from and the benefit of Korean Patent Application No. 10-2011-0134130, filed on Dec. 14, 2011, Korean Patent Application No. 10-2011-0135513, filed on Dec. 15, 2011, Korean Patent Application No. 10-2012-0026879, filed on Mar. 16, 2012, and Korean Patent Application No. 10-2012-0026948, filed on Mar. 16, 2012, which are hereby incorporated by reference for all purposes as if fully set forth herein.

### BACKGROUND

1. Field

The present invention relates to a semiconductor device and a method of fabricating the same, and more particularly, to a light emitting diode and a method of fabricating the same.

2. Discussion of the Background

In general, since Group III nitrides such as gallium nitride (GaN) and aluminum nitride (AlN) have excellent thermal stability and a direct-transition-type energy band structure, the Group III nitrides have recently come into the spotlight as materials for light emitting devices in visible and ultraviolet regions. Particularly, blue and green light emitting devices using indium gallium nitride (InGaN) have been utilized in various applications such as large-sized full-color flat panel displays, traffic lights, indoor illumination, high-density light sources, high-resolution output systems, optical communications and the like.

Since it was difficult to fabricate a homogeneous substrate on which a Group III nitride semiconductor layer could be grown, the Group III nitride semiconductor layer has been grown on a heterogeneous substrate having a similar crystal structure to the Group III nitride semiconductor layer through a process such as metal organic chemical vapor deposition (MOCVD) or molecular beam epitaxy (MBE). A sapphire substrate having a hexagonal crystal system structure, particularly a sapphire substrate having c-plane as a growth surface is frequently used as the heterogeneous substrate. Recently, there has been developed a technique for fabricating a high-efficiency light emitting diode (LED) with a vertical structure by growing epitaxial layers such as nitride semiconductor layers on a heterogeneous substrate such as a sapphire substrate, bonding a support substrate to the epitaxial layers and then separating the heterogeneous substrate using a laser lift-off technique or the like. Since the heterogeneous substrate such as the sapphire substrate and the epitaxial layer grown on the heterogeneous substrate have different physical properties, the growth substrate can be easily separated using the interface between the heterogeneous substrate and the epitaxial layer.

However, the epitaxial layer grown on the heterogeneous substrate has a relatively higher dislocation density due to lattice mismatch between the epitaxial layer and the growth substrate and a difference in thermal expansion coefficient between the epitaxial layer and the growth substrate. The epitaxial layer grown on the sapphire substrate generally has a dislocation density of 1 E8/cm² or more. There is a limitation in improving the light emitting efficiency of the LED using the epitaxial layer having such a high dislocation density.

Moreover, a GaN-based compound semiconductor layer grown in the c-axis direction has a polarity caused by spontaneous polarization and piezoelectric polarization. Therefore, the recombination rate of electrons and holes is lowered, and there is a limitation in improving light emitting efficiency.

Meanwhile, studies have recently been conducted to fabricate an LED by growing an epitaxial layer using a GaN substrate as a growth substrate. However, since the GaN substrate is homogeneous with the epitaxial layer grown thereon, it is difficult to fabricate the high-efficiency LED with the vertical structure by separating the GaN substrate from the epitaxial layer.

Since a GaN-based compound semiconductor layer grown on a-plane or m-plane is non-polar, the spontaneous polarization or the piezoelectric polarization does not occur in the GaN-based compound semiconductor layer. However, the growth of the GaN-based compound semiconductor layer on a-plane or m-plane has many problems to be solved, and therefore has not been widely applied yet.

### SUMMARY

An object of the present invention is to provide a high-efficiency light emitting diode (LED) with a vertical structure in which a growth substrate is removed, and a method of fabricating the same.

Another object of the present invention is to provide a method of fabricating a high-efficiency LED with a vertical structure in which a gallium nitride (GaN) growth substrate is removed.

A further object of the present invention is to provide a high-efficiency LED having improved light extraction efficiency, and a method of fabricating the same.

A still further object of the present invention is to provide a method of fabricating a non-polar or semi-polar LED.

A still further object of the present invention is to provide a semiconductor device substrate having a seed layer that has a material, lattice constant or thermal expansion coefficient identical or similar to those of a semiconductor layer to be grown thereon, and a method of fabricating a semiconductor device using the semiconductor device substrate.

### Solution to Problem

The present invention provides a semiconductor device, particularly a light emitting diode (LED), and a method of fabricating the same. According to an aspect of the present invention, there is provided an LED including: a support substrate; a semiconductor stack positioned on the support substrate and having a gallium nitride (GaN)-based p-type semiconductor layer, a GaN-based active layer and a GaN-based n-type semiconductor layer; a p-electrode layer in ohmic contact with the p-type semiconductor layer between the support substrate and the semiconductor stack; and a transparent oxide layer positioned on the semiconductor stack and having a concavo-convex pattern, wherein the semiconductor stack is formed to have a dislocation density of 5×10⁶/cm² or less.

Thus, it is possible to alleviate a droop phenomenon of the LED, which could be generated by an increase in the dislocation density due to a low dislocation density and crystal qualities of the semiconductor layers. The semiconductor stack may be formed of the semiconductor layers grown on a GaN substrate. In addition, it is possible to extract light using the transparent oxide layer having the concavo-convex pattern, thereby improving light extraction efficiency of the LED.

According to another aspect of the present invention, there is provided an LED including: a support substrate; a semiconductor stack positioned on the support substrate and having a GaN-based p-type semiconductor layer, a GaN-based active layer and a GaN-based n-type semiconductor layer; a p-electrode layer in ohmic contact with the p-type semiconductor layer between the support substrate and the semiconductor stack; an n-electrode layer positioned between the support substrate and the semiconductor stack and connected to the n-type semiconductor layer through a through-hole penetrating the p-type semiconductor layer and the active layer; and an insulation layer for insulating the p-electrode layer and the n-electrode layer from each other, wherein the semiconductor stack is formed to have a dislocation density of 5×10⁶/cm² or less.

By disposing the p-electrode layer and the n-electrode layer between the semiconductor stack and the support substrate, it is possible to prevent occurrence of light loss at a light emission surface.

According to a further aspect of the present invention, there is provided a method of fabricating an LED, including: forming a first GaN layer, a sacrificial layer and a second GaN layer on a GaN substrate, wherein the sacrificial layer has a bandgap narrower than those of the GaN layers; forming a groove penetrating the second GaN layer and the sacrificial layer; growing GaN-based semiconductor layers on the second GaN layer to form a semiconductor stack; forming a support substrate on the semiconductor stack; and removing the GaN substrate from the semiconductor stack by etching the sacrificial layer.

The sacrificial layer may be etched using a photo-enhanced chemical etching technique.

According to a still further aspect of the present invention, there is provided a method of fabricating an LED, including: forming a GaN layer and a sacrificial layer on a GaN substrate. The sacrificial layer is formed of a GaN-based semiconductor having a bandgap narrower than that of the GaN layer. The method further includes growing GaN-based semiconductor layers on the sacrificial layer to form a semiconductor stack; forming a groove penetrating the semiconductor stack and the sacrificial layer; forming a support substrate on the semiconductor stack; and separating the GaN substrate from the semiconductor stack by etching the sacrificial layer.

The sacrificial layer may be formed of InGaN. The etching of the sacrificial layer may be performed using a photo-enhanced chemical etching technique. For example, the etching of the sacrificial layer may be performed by irradiating the sacrificial layer with light through the GaN substrate in a KOH or NaOH solution.

After the GaN substrate is removed, a transparent oxide layer having a concavo-convex pattern may be formed on the n-type semiconductor layer.

The semiconductor stack includes a GaN-based n-type semiconductor layer, a GaN-based active layer and a GaN-based p-type semiconductor layer. The method may further include forming a p-type electrode layer in ohmic contact with the p-type semiconductor layer of the semiconductor stack, before forming the support substrate.

In some embodiments, the method may further include forming a filler for filling the groove, before forming the support substrate. Before the filler is formed, the p-electrode layer may be formed to be restricted within the range of the semiconductor stack. Alternatively, after the filler is formed, the p-electrode layer may be formed to cover the semiconductor stack and the filler.

The method may further include forming a bonding pad beneath the support substrate.

According to a still further aspect of the present invention, there is provided a method of fabricating an LED, including: a conductive substrate; and a gallium nitride (GaN)-based semiconductor stack positioned on the substrate. Here, the semiconductor stack includes an active layer as a semi-polar semiconductor layer.

The GaN-based semiconductor stack includes semiconductor layers grown on a semi-polar GaN substrate. The semi-polar GaN substrate may be a miscut semi-polar GaN substrate having a principal surface inclined at an angle ranging from 15 to 80 degrees with respect to c-plane.

In some embodiments, the conductive substrate may be the semi-polar GaN substrate but is not limited thereto. For example, the substrate may be a metal substrate attached to the semiconductor stack. Further, a reflective layer may be positioned between the conductive substrate and the semiconductor stack.

The LED may further include a transparent oxide layer positioned on the semiconductor stack, and the transparent oxide layer may have a concavo-convex pattern. An upper surface of the semiconductor stack adjacent to the transparent oxide layer may have a concavo-convex pattern.

According to a still further aspect of the present invention, there is provided a method of fabricating an LED, including: preparing a miscut semi-polar GaN substrate having a principal surface inclined at an angle ranging from 15 to 85 degrees with respect to c-plane; and growing semi-polar GaN-based semiconductor layers on the substrate to form a semiconductor stack.

The method may further include forming a transparent oxide layer on the semiconductor stack. The transparent oxide layer may have a concavo-convex pattern.

In some embodiments, the method may further include forming a reflective layer on the semiconductor stack; attaching a support substrate on the reflective layer; and removing the semi-polar GaN substrate.

Before the semiconductor stack is formed on the substrate, a nitride layer with a porous structure may be formed on the semi-polar GaN substrate using an electrochemical etching technique. The nitride layer with the porous structure may be used to separate the semi-polar GaN substrate from the semiconductor stack.

After the semi-polar GaN substrate is removed, a concavo-convex pattern may be formed on a surface of the semiconductor stack.

According to a still further aspect of the present invention, there is provided a method of fabricating a semiconductor device, including: preparing a support substrate and a bulk substrate; forming a joining layer on one surface of the support substrate; joining the bulk substrate on the one surface of the support substrate using the joining layer; and cutting the bulk substrate to a predetermined thickness from the joining layer and separating it to form a seed layer.

The bulk substrate may include GaN.

The bulk substrate may be fabricated using a hydride vapor phase epitaxy (HVPE) technique, Na flux technique, or ammonothermal technique.

The joining layer may be made of an oxide including at least on of Zn, Si, Ga and Al or a nitride including at least one of Si, Ga or Al.

The method may further include forming a metallic intermediate layer on the joining layer, before joining the support substrate and the bulk substrate.

When the support substrate and the bulk substrate are joined together, the metallic intermediate layer may be formed in the shape of islands.

The support substrate may be a sapphire substrate, MN substrate, Ge substrate or SiC substrate.

The support substrate may have a concavo-convex pattern formed on one surface thereof.

The method may further include, after forming the seed layer, forming a plurality of semiconductor layers including at least a first conductive semiconductor layer, an active layer and a second conductive semiconductor layer on the seed layer; patterning the semiconductor layers to form a semiconductor stack in which a portion of the first conductive semiconductor layer is exposed; forming a transparent conductive oxide (TCO) layer on the second conductive semiconductor layer of the semiconductor stack; and forming first and second electrodes on the exposed first conductive semiconductor layer and the TCO layer, respectively.

The method may further include planarizing a surface of the seed layer, before forming the plurality of semiconductor layers.

The TCO layer may include concavo-convex portions on a surface thereof.

The formation of the TCO layer on the second conductive semiconductor layer may include forming a first TCO layer on the semiconductor stack; forming a photoresist pattern on the first TCO layer; forming a second TCO layer on the first TCO layer having the photoresist pattern formed thereon; and removing portions of the photoresist pattern and the second TCO layer formed on the photoresist pattern using a lift-off technique.

The formation of the TCO layer on the second conductive semiconductor layer may include forming a photoresist pattern having a plurality of open regions on the TCO layer; and forming concavo-convex portions on a surface of the TCO layer by wet-etching the surface of the TCO layer to a predetermined depth using the photoresist pattern as a mask.

The method may further include, after forming the seed layer, forming a plurality of semiconductor layers including at least a first conductive semiconductor layer, an active layer and a second conductive semiconductor layer on the seed layer; forming an etch stop pattern on the second conductive semiconductor layer of the plurality of semiconductor layers; forming a metal bonding layer on the seed layer having the etch stop pattern formed thereon; forming a metal substrate on the metal bonding layer; separating the support substrate; patterning the plurality of semiconductor layers to form a semiconductor stack; forming a TCO layer on a surface exposed by separation of the support substrate; and forming an electrode pad on the TCO layer.

The method may further include removing the seed layer, before forming the TCO layer after separating the support substrate.

The method may further include forming an ohmic reflective pattern between the plurality of semiconductor layers and the metal bonding layer before forming the metal bonding layer after forming the plurality of semiconductor layers.

The ohmic reflective pattern may be positioned in open regions of the etch stop pattern.

The method may further include planarizing a surface of the seed layer before forming the plurality of semiconductor layers.

The TCO layer may include concavo-convex portions formed on a surface thereof.

The formation of the TCO layer on the surface from which the support substrate has been separated may include forming a first TCO layer on the surface from which the support substrate has been separated; forming a photoresist pattern on the first TCO layer; forming a second TCO layer on the first TCO layer having the photoresist pattern formed thereon; and removing portions of the photoresist pattern and the second TCO layer formed on the photoresist pattern using a lift-off technique.

The formation of the TCO layer on the surface from which the support substrate has been separated may include forming a photoresist pattern having a plurality of open regions on the surface from which the support substrate has been separated; and forming a concavo-convex portions on a surface of the TCO layer by wet-etching the surface of the TCO layer to a predetermined depth using the photoresist pattern as a mask.

According to the present invention, semiconductor layers are grown using a gallium nitride (GaN) substrate as a growth substrate, so that it is possible to form a semiconductor stack having a low dislocation density. Further, a light emitting diode (LED) with a vertical structure can be fabricated by removing the GaN substrate from the semiconductor stack, thereby providing a high-efficiency LED. Since the dislocation density of the semiconductor layers grown on the GaN substrate is very low, there is a limitation in providing a roughened surface using the conventional photo-enhanced chemical etching, and therefore, it is difficult to improve light extraction efficiency. However, according to the present invention, it is possible to improve light extraction efficiency of the LED using a transparent oxide layer having a concavo-convex pattern.

Further, since the GaN substrate is separated from the semiconductor stack by etching a sacrificial layer, the GaN substrate can be reused.

Meanwhile, an LED including an active layer as a semi-polar semiconductor layer is provided, so that polarization can be reduced or removed, thereby improving light emitting efficiency. Further, semiconductor layers are grown using a miscut GaN substrate, so that the semi-polar semiconductor layer can be relatively easily grown. In addition, the GaN substrate is separated through an electrochemical etching technique, so that it is possible to reuse the GaN substrate, resulting in reduced fabrication cost.

Further, it is possible to fabricate a semiconductor device substrate having a seed layer that has a material, lattice constant or thermal expansion coefficient identical or similar to those of a semiconductor layer to be grown thereon, and to fabricate a semiconductor device using the semiconductor device substrate.

### BRIEF DESCRIPTION OF THE DRAWINGS

FIG. 1 is a sectional view illustrating a light emitting diode (LED) according to an embodiment of the present invention.

FIGS. 2 to 6 are sectional views illustrating a method of fabricating an LED according to an embodiment of the present invention.

FIG. 7 is a schematic view illustrating a process of separating a gallium nitride (GaN) substrate according to an embodiment of the present invention.

FIG. 8 is a sectional view illustrating an LED according to another embodiment of the present invention.

FIGS. 9 to 12 are sectional views illustrating a method of fabricating an LED according to the other embodiment of the present invention.

FIGS. 13 to 19 are sectional and plan views illustrating a method of fabricating an LED according to a further embodiment of the present invention.

FIG. 20 is a schematic view illustrating a process of separating a GaN substrate according to an embodiment of the present invention.

FIG. 21 is a sectional view illustrating a miscut GaN substrate.

FIG. 22 is a sectional view illustrating an LED according to an embodiment of the present invention.

FIG. 23 is a sectional view illustrating an LED according to an embodiment of the present invention.

FIGS. 24 to 26 are sectional views illustrating the method of fabricating the LED of FIG. 23.

FIG. 27 is a sectional view illustrating a separated GaN substrate.

FIGS. 28 to 30 are sectional views illustrating a method of fabricating a semiconductor device according to a still further embodiment of the present invention.

FIG. 31 is a sectional view illustrating another type of support substrate in the method of the present invention.

FIGS. 32 and 33 are sectional and plan views illustrating a method of fabricating a semiconductor device according to a still further embodiment of the present invention.

FIGS. 34 and 35 are sectional views illustrating a method of forming a concavo-convex pattern on a surface of a transparent conductive oxide (TCO) layer.

FIGS. 36 and 37 are sectional views illustrating a method of fabricating a semiconductor device according to a still further embodiment of the present invention.

### DETAILED DESCRIPTION OF THE ILLUSTRATED EMBODIMENTS

Hereinafter, preferred embodiments of the present invention will be described in detail with reference to the accompanying drawings. The following embodiments are provided only for illustrative purposes so that those skilled in the art can fully understand the spirit of the present invention. Therefore, the present invention is not limited to the following embodiments but may be implemented in other forms. In the drawings, the widths, lengths, thicknesses and the like of elements are exaggerated for convenience of illustration. Like reference numerals indicate like elements throughout the specification and drawings.

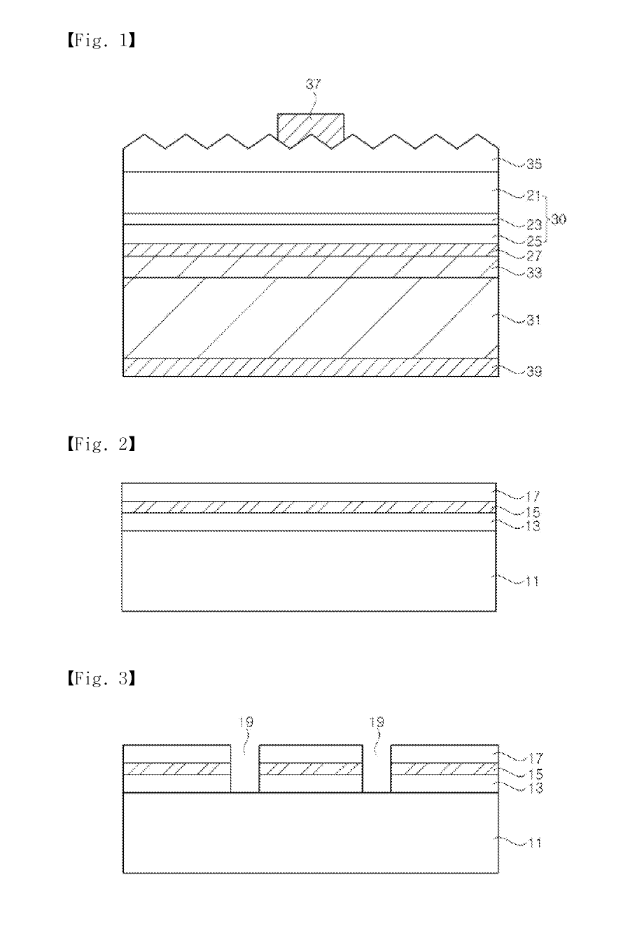

FIG. 1 is a sectional view illustrating a light emitting diode (LED) according to an embodiment of the present invention.

Referring to FIG. 1, the LED may include a support substrate 31, a semiconductor stack 30, a p-electrode layer 27, a bonding metal 33, a transparent oxide layer 35 and an n-electrode pad 37. The LED may further include a bonding pad 39.

The support substrate 31 is distinguished from a growth substrate for growing compound semiconductor layers thereon. The support substrate 31 is a secondary substrate attached to the compound semiconductor layers that have already been grown. The support substrate 31 may be a conductive substrate, e.g., a metal substrate or semiconductor substrate.

The semiconductor stack 30 is positioned on the support substrate 31, and includes a p-type compound semiconductor layer 25, an active layer 23 and an n-type compound semiconductor layer 21. In the semiconductor stack 30, the p-type compound semiconductor layer 25 is positioned closer to the support substrate 31 than the n-type compound semiconductor layer 21.

The n-type compound semiconductor layer 21, the active layer 23 and the p-type compound semiconductor layer 25 may be formed of a Group III-N based compound semiconductor, e.g., an (Al, Ga, In)N semiconductor. Each of the n-type and p-type compound semiconductor layers 21 and 25 may be formed as a single layer or multilayer. For example, the n-type compound semiconductor layer 21 and/or the p-type compound semiconductor layer 25 may include a contact layer and a clad layer, and may further include a superlattice layer. The active layer 23 may have a single or multiple quantum well structure.

The semiconductor stack 30 may be formed to have a dislocation density of 5×10⁶/cm² or less. Generally, semiconductor layers grown on a sapphire substrate have a higher dislocation density of 1×10⁸/cm² or more. On the other hand, when the semiconductor stack 30 according to the present invention uses the semiconductor layers 21, 23 and 25 grown using a gallium nitride (GaN) substrate as a growth substrate, the semiconductor stack 30 may be formed to have a lower dislocation density of 5×10⁶/cm² or less. The lower limit of the dislocation density is not particularly limited, but may be no less than 1×10⁴/cm² or no less than 1×10⁶/cm². If the dislocation density in the semiconductor stack 30 is lowered, a droop that could be generated due to the increase of the current may be alleviated.

The p-electrode layer 27 is positioned between the p-type compound semiconductor layer 25 and the support substrate 31. The p-electrode layer 27 is in ohmic contact with the p-type compound semiconductor layer 25, and may include a reflective metal layer and a barrier metal layer. The reflective metal layer may include, for example, a reflective layer such as Ag. The barrier metal layer covers the reflective metal layer so as to prevent diffusion of a metallic material of the reflective metal layer, e.g., Ag. The barrier metal layer may include, for example, a Ni layer.

Meanwhile, the support substrate 31 may be bonded on the p-electrode layer 27 through the bonding metal 33. The bonding metal 33 may be formed through, for example, Au—Sn eutectic bonding. Alternatively, the support substrate 31 may be formed on the p-electrode layer 27 using a plating technique.

The bonding pad 39 is formed beneath the support substrate 31. The bonding pad 39 may be formed of a metallic material such as Au—Sn suitable for eutectic bonding. The bonding pad 39 is used when the LED is mounted on a printed circuit board, lead frame or the like. The bonding pad 39 is formed of a metallic material having a high thermal conductivity so as to improve the heat dissipation characteristic of the LED.

The transparent oxide layer 35 may be positioned on the semiconductor stack 30, i.e., the n-type compound semiconductor layer 21. The transparent oxide layer 35 may be patterned to have a concavo-convex pattern on a surface thereof. The transparent oxide layer 35 may be formed of a layer of a conductive oxide such as zinc oxide (ZnO) or indium tin oxide (ITO), or a layer of an insulative oxide such as silicon oxide (SiO₂). The transparent oxide layer 35 can satisfactorily emit light generated in the semiconductor stack 30 to the outside of the LED by the concavo-convex pattern.

The n-electrode pad 37 may be positioned on the transparent oxide layer 35. The n-electrode pad 37 may be electrically connected to the n-type compound semiconductor layer 21 through the transparent oxide layer 35. Alternatively, the n-electrode pad 37 may come in direct contact with the n-type compound semiconductor layer 21. To this end, an opening for exposing the n-type compound semiconductor layer 21 therethrough may be formed in the transparent oxide layer 35.

In this embodiment, although it has been described that the transparent oxide layer 35 having the concavo-convex pattern is positioned on the n-type compound semiconductor layer 21, a roughened surface or a concavo-convex pattern for light extraction may be formed in a surface of the n-type compound semiconductor layer 21 instead of or in addition to the transparent oxide layer 35.

FIGS. 2 to 6 are sectional views illustrating a method of fabricating an LED according to an embodiment of the present invention.

Referring to FIG. 2, a first GaN layer 13, a sacrificial layer 15 and a second GaN layer 17 are grown on a GaN substrate 11. Here, the sacrificial layer 15 may be formed as a GaN-based layer, e.g., an InGaN layer having a bandgap narrower than that of the first GaN layer 13. The first GaN layer 13 may be formed of undoped-GaN without intentionally doping impurities, and the sacrificial layer 15 may be formed by means of doping of an n-type impurity such as Si. The first GaN layer 13 performs a function of preventing the GaN substrate 11 from being damaged when the sacrificial layer 15 is etched.

Meanwhile, the second GaN layer 17 may be formed of undoped-GaN without intentionally doping impurities and may be used as a seed layer for growing an epitaxial layer later.

Referring to FIG. 3, a groove 19 is formed by patterning the second GaN layer 17 and the sacrificial layer 15. The groove 19 may penetrate the first GaN layer 13. The groove 19 may be formed using a dry etching technique or laser scribing technique. Since the second GaN layer 17 and the first GaN layer 13 are used, the depth of the groove 19 is greater than the thickness of the sacrificial layer 15.

A plurality of grooves 19 may be arranged in the shape of stripes or may be arranged in the shape of a mesh interconnected to one another. The interval between two adjacent grooves 19 is preferably about 1 cm or less. Further, the grooves 19 may be formed to correspond to the size of chips of the LED, or may be formed more densely.

Referring to FIG. 4, a semiconductor stack 30 including a GaN-based n-type semiconductor layer 21, a GaN-based active layer 23 and a GaN-based p-type semiconductor layer 25 is formed on the second GaN layer 17. The n-type semiconductor layer 21 is grown on the second GaN layer 17 and covers the grooves 19 through lateral growth. The active layer 23 and the p-type semiconductor layer 25 are grown on the n-type semiconductor layer 21.

Each of the n-type and p-type semiconductor layers 21 and 25 may be formed as a single layer or multilayer. The active layer 23 may be formed to have a single or multiple quantum well structure. The semiconductor layers 21, 23 and 25 are grown on the GaN substrate 11 so as to have a dislocation density of about 5×10⁶/cm² or less.

The first and second GaN layers 13 and 17, the sacrificial layer 15 and the compound semiconductor layers 21, 23 and 25 may be grown through a process including a metal organic chemical vapor deposition (MOCVD), molecular beam epitaxy (MBE) or the like.

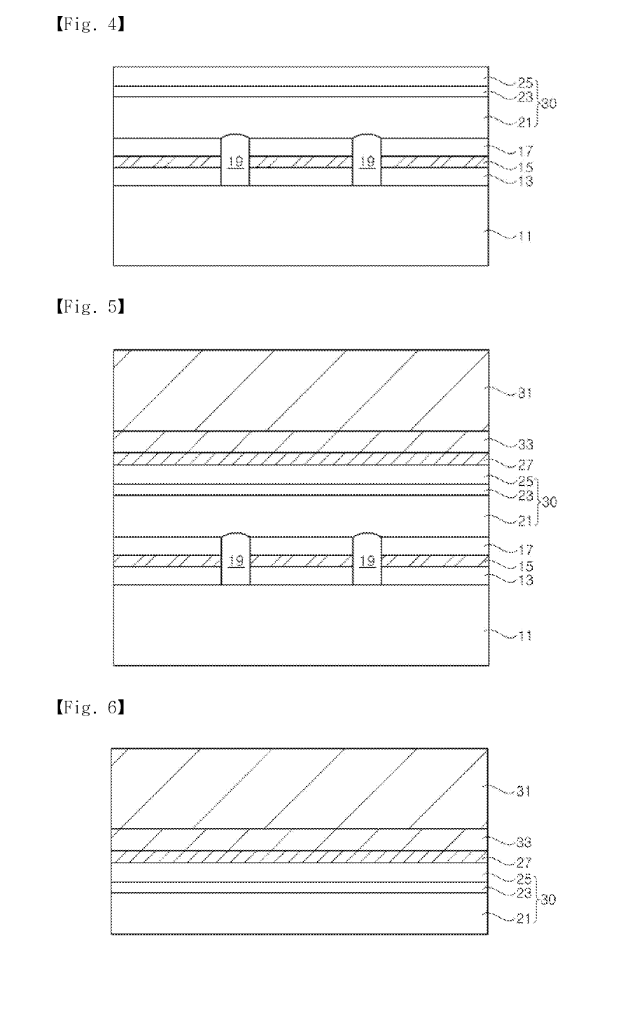

Referring to FIG. 5, a p-electrode layer 27 is formed on the semiconductor stack 30. The p-electrode layer 27 is in ohmic contact with the p-type semiconductor layer 25. The p-electrode layer 27 may include a reflective metal layer and a barrier metal layer.

Subsequently, a support substrate 31 is attached on the p-electrode layer 27. The support substrate 31 may be fabricated separately from the semiconductor stack 30 and then bonded on the p-electrode layer 27 through a bonding metal 33. Alternatively, the support substrate 31 may be formed on the p-electrode layer 27 through a plating technique. The support substrate 31 may be a conductive substrate, e.g., a metal or semiconductor substrate.

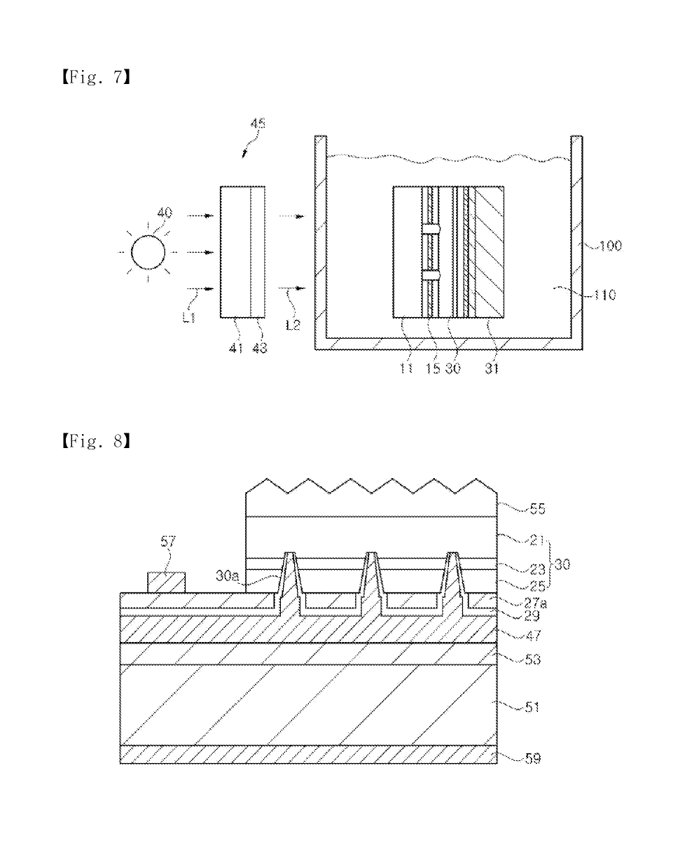

Referring to FIG. 6, after the support substrate 31 is formed, the GaN substrate 11 is removed and the second GaN layer 17 is removed, so that a surface of the n-type semiconductor layer 21 of the semiconductor stack 30 is exposed. The second GaN layer 17 may be removed using a dry etching, grinding, or polishing technique.

The GaN substrate 11 may be separated from the semiconductor stack 30 using a photo-enhanced chemical etching technique. FIG. 7 is a schematic view illustrating a process of separating the GaN substrate 11.

Referring to FIG. 7, after the support substrate 31 is formed as described with reference to FIG. 5, the entire object including the GaN substrate 11 is immersed in a bath 100 containing a KOH or NaOH solution 110. Then, light is irradiated toward the GaN substrate 11 using an ultraviolet (UV) lamp 40. In this case, light of a wavelength that would be absorbed by the GaN substrate 11 among light L1 generated from the UV lamp 40 is pre-filtered using a filter 45, except for light L2 of a wavelength to be absorbed by the sacrificial layer 15. The filter 45 may be formed, for example, by growing a GaN layer 43 on a sapphire substrate 41. Thus, the GaN layer 43 blocks, in advance, the light of the wavelength that would be absorbed by the GaN substrate 11.

Accordingly, the light L2 that is transmitted through the GaN substrate 11 is irradiated onto the sacrificial layer 15 through the GaN substrate 11 in the bath 100. Side surfaces of the sacrificial layer 15 are exposed to inner walls of the grooves 19 and also absorb the light L2. Thus, the sacrificial layer 15 is etched by the KOH or NaOH solution 110 penetrating into the grooves 19.

The light may be irradiated by using, instead of the UV lamp 40, a laser or LED that emits light of a specific wavelength, i.e., light of a wavelength that will be transmitted through the GaN substrate 11 and absorbed by the sacrificial layer 15.

According to this embodiment, since the grooves 19 are formed on the substrate 11, the sacrificial layer 15 is etched in an edge region as well as an inner region of the substrate 11. Thus, the GaN substrate 11 can be easily separated from the semiconductor stack 30 even when the size of the substrate 11 is relatively large. Further, the etching time of the sacrificial layer 15 can be appropriately controlled by adjusting the interval between two adjacent grooves 19.

After the GaN substrate 11 is removed, the second GaN layer 17 may be removed as described above. Accordingly, a surface of the n-type semiconductor layer 21 is exposed and the n-type semiconductor layer 21 is partially etched to form a roughened surface or concavo-convex pattern. The concavo-convex pattern may be formed by vapor depositing a transparent oxide layer (35 of FIG. 1) on the n-type semiconductor layer 21 and patterning the deposited transparent oxide layer. Then, an n-electrode pad 37 and a bonding pad 39 may be formed, and the semiconductor stack 30 is divided into individual LEDs, thereby resulting in the completed LED of FIG. 1.

If a conventional sapphire substrate is used as the growth substrate, the sapphire substrate can be easily separated using an interface between the substrate and the semiconductor layers, since the sapphire substrate has physical properties different from those of semiconductor layers grown on the sapphire substrate. However, if the GaN substrate 11 is used as the growth substrate, it is difficult to separate the substrate 11 using the interface between the substrate 11 and the semiconductor layers 21, 23 and 25, since the GaN substrate 11 and the semiconductor layers 21, 23 and 25 grown on the GaN substrate 11 are made of a homogeneous material.

Accordingly, in the present invention, the GaN substrate 11 is separated using the sacrificial layer 15. Thus, the GaN substrate 11 can be separated from the semiconductor stack without damaging the GaN substrate 11. Since the separated GaN substrate 11 is not damaged, the GaN substrate 11 can be reused as the growth substrate.

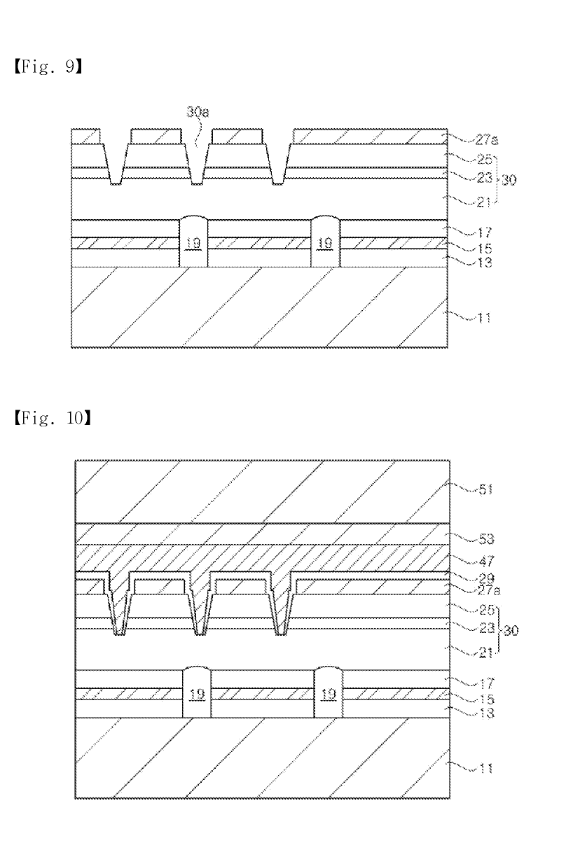

FIG. 8 is a sectional view illustrating an LED according to another embodiment of the present invention.

Referring to FIG. 8, the LED includes a support substrate 51, a semiconductor stack 30, a p-electrode layer 27a, an insulation layer 29, an n-electrode layer 47, a bonding metal 53, a transparent oxide layer 55 and a p-electrode pad 57. The LED may further include a bonding pad 59.

Here, since the semiconductor stack 30, the support substrate 51, the bonding metal 53, the transparent oxide layer 55 and the bonding pad 59 are similar to those of the LED of FIG. 1, detailed descriptions thereof will be omitted. However, the semiconductor stack 30 may be positioned on a partial region of the support substrate 51. That is, the support substrate 51 has an area relatively wider than that of the semiconductor stack 30, and the semiconductor stack 30 is positioned on the partial region of the support substrate 51. Further, the semiconductor stack 30 has a through-hole 30a penetrating the p-type semiconductor layer 25 and the active layer 23. A plurality of through-holes 30a may be formed to be uniformly distributed.

Similarly to the p-electrode layer 27 described with reference to FIG. 1, the p-electrode layer 27a is in ohmic contact with the p-type semiconductor layer 25, and may include a reflective metal layer and a barrier metal layer. The p-electrode layer 27a is in contact with the p-type semiconductor layer 25 and has openings for exposing the through-holes 30a therethrough.

The n-electrode layer 47 is positioned between the semiconductor stack 30 and the support substrate 51, and is electrically connected to the n-type semiconductor layer 21 through the through-holes 30a. The n-electrode layer 47 is spaced apart and insulated from the p-electrode layer 27a, the p-type semiconductor layer 25 and the active layer 23.

The insulation layer 29 is positioned between the n-electrode layer 47 and the p-electrode layer 27a, so that the n-electrode layer 47 and the p-electrode layer 27a are spaced apart from each other. For example, the insulation layer 29 covers a lower surface of the p-electrode layer 27a. Further, the insulation layer 29 covers the inner walls of the through-holes 30a so as to insulate the p-type semiconductor layer 25 and the active layer 23 from the n-electrode layer 47.

The p-electrode layer 27a extends to the outside of a lower region of the semiconductor stack 30, and the p-electrode pad 57 is positioned on the extended p-electrode layer 27a.

According to this embodiment, the n-electrode layer 47 is positioned between the support substrate 51 and the semiconductor stack 30. Thus, it is possible to prevent light emitted from the active layer 23 through the transparent oxide layer 55 from being lost by the n-electrode pad 37 shown in FIG. 1. If the plurality of through-holes 30a are used, the n-electrode layer 47 may be in contact with the n-type semiconductor layer 21 at multiple points in the n-type semiconductor layer 21, and thus, the current can be equally dispersed in the LED.

FIGS. 9 to 12 are sectional views illustrating a method of fabricating an LED according to a further embodiment of the present invention.

Referring to FIG. 9, a first GaN layer 13, a sacrificial layer 15 and a second GaN layer 17 are grown on a GaN substrate 11; grooves 19 are formed; and a semiconductor stack 30 including an n-type semiconductor layer 21, an active layer 23 and a p-type semiconductor layer 25 is grown on the second GaN layer 17, as described with reference to FIGS. 2 to 4.

Then, a p-electrode layer 27a is formed on the semiconductor stack 30. The p-electrode layer 27a is formed to have openings. Subsequently, a through-hole 30a penetrating the second semiconductor layer 25 and the active layer 23 is formed by patterning the semiconductor stack 30. The p-electrode layer 27a may be formed after the formation of the through-hole 30a. For the through-hole 30a, one or a plurality of through-hole(s) may be formed in one LED region.

Referring to FIG. 10, an insulation layer 29 is formed to cover the p-electrode layer 27a. The insulation layer 29 may also cover the inner wall of the through-hole 30a. The insulation layer 29 may be formed of a silicon oxide or a silicon nitride. Further, the insulation layer 29 may be formed as a distributed Bragg reflector (DBR) by alternately vapor depositing SiO₂ and TiO₂. The insulation layer 29 has an opening for exposing the n-type semiconductor layer 21 at the bottom of the through-hole 30a.

An n-electrode layer 47 is formed in the insulation layer 29. The n-electrode layer 47 is electrically connected to the n-type semiconductor layer 21 through the through-hole 30a. The n-electrode layer 47 is electrically insulated from the p-electrode layer 27a by the insulation layer 29. The n-electrode layer 47 is also spaced apart from the p-type semiconductor layer 25 and the active layer 23.

Then, a support substrate 51 is attached on the n-electrode layer 47. After being fabricated separately from the semiconductor stack 30, the support substrate 51 may be bonded on the n-electrode layer 47 through a bonding metal 53. Alternatively, the support substrate 51 may be formed on the n-electrode layer 47 through a plating technique. The support substrate 51 may be a conductive substrate, e.g., a metal or semiconductor substrate.

Referring to FIG. 11, after the support substrate 51 is formed, the GaN substrate 11 is removed and the second GaN layer 17 is removed, so that a surface of the n-type semiconductor layer 21 of the semiconductor stack 30 is exposed, as described with reference to FIG. 6.

As described with reference to FIG. 7, the GaN substrate 11 may be separated from the semiconductor stack 30 using the photo-enhanced chemical etching technique, and a detailed description thereof will be omitted to avoid redundancy.

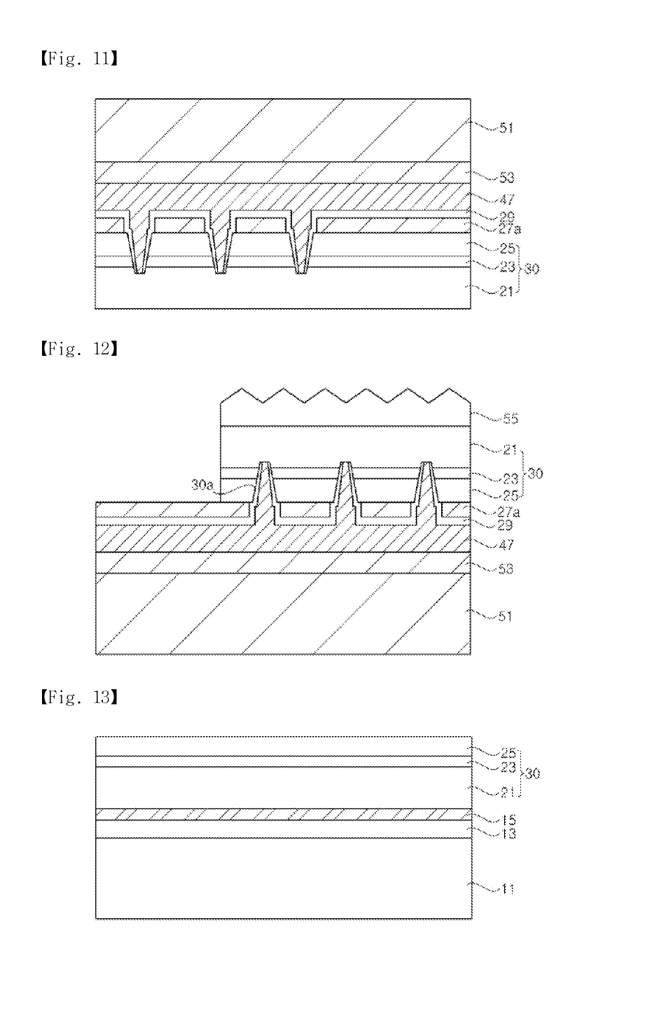

Referring to FIG. 12, a transparent oxide layer 55 having a concavo-convex pattern is formed on the exposed n-type semiconductor layer 21. Meanwhile, a portion of the semiconductor stack 30 is removed to expose a portion of the p-electrode layer 27a, and a p-electrode pad 57 is formed on the exposed p-electrode layer 27a as shown in FIG. 8. A bonding pad 59 may be formed at the bottom of the support substrate 51, and the semiconductor stack 30 is divided into individual LEDs, thereby resulting in the completed LED of FIG. 8.

According to this embodiment, the n-electrode layer 47 is disposed between the semiconductor stack 30 and the support substrate 51, thereby providing an LED capable of preventing light loss at a light emission surface.

FIGS. 13 to 19 are sectional and plan views illustrating a method of fabricating an LED according to a still further embodiment of the present invention, in which FIG. 15 is a plan view and the others are sectional views.

Referring to FIG. 13, a GaN layer 13 and a sacrificial layer 15 are grown on a GaN substrate 11. Here, the sacrificial layer 15 may be formed as a GaN-based layer, e.g., an InGaN layer having a bandgap narrower than that of the GaN layer 13. The first GaN layer 13 may be formed of undoped-GaN without intentionally doping impurities, and the sacrificial layer 15 may be formed by means of doping of an n-type impurity such as Si. The GaN layer 13 performs a function of preventing the GaN substrate 11 from being damaged when the sacrificial layer 15 is etched.

A semiconductor stack 30 including a GaN-based n-type semiconductor layer 21, a GaN-based active layer 23 and a GaN-based p-type semiconductor layer 25 is formed on the sacrificial layer 15.

Each of the n-type and p-type semiconductor layers 21 and 25 may be formed as a single layer or multilayer. The active layer 23 may be formed to have a single or multiple quantum well structure. If the semiconductor layers 21, 23 and 25 are grown on the GaN substrate 11, they may be formed to have a dislocation density of about 5×10⁶/cm² or less.

The GaN layer 13, the sacrificial layer 15 and the compound semiconductor layers 21, 23 and 25 may be grown through a process including the MOCVD, MBE, or the like.

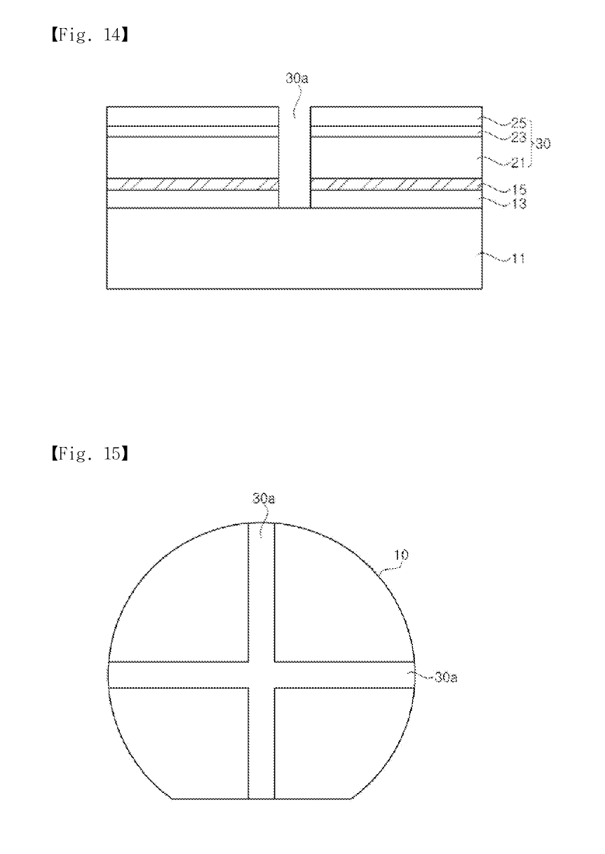

Referring to FIG. 14, the semiconductor stack 30 and the sacrificial layer 15 is patterned to form grooves 30a. The grooves 30a may penetrate the GaN layer 13. The grooves 30a may be formed using a dry etching technique or laser scribing technique.

As shown in FIG. 15, the grooves 30a may be formed to divide the semiconductor stack 30 into four equal parts on a wafer 10. However, the shape of the grooves 30a is not limited to that of FIG. 15, and may be variously changed depending on the size of the substrate 11. Here, the size of each of regions defined by the grooves 30a or the size of each of regions defined by the grooves 30a and an edge of the wafer 10 is identical to or relatively larger than that of an LED chip.

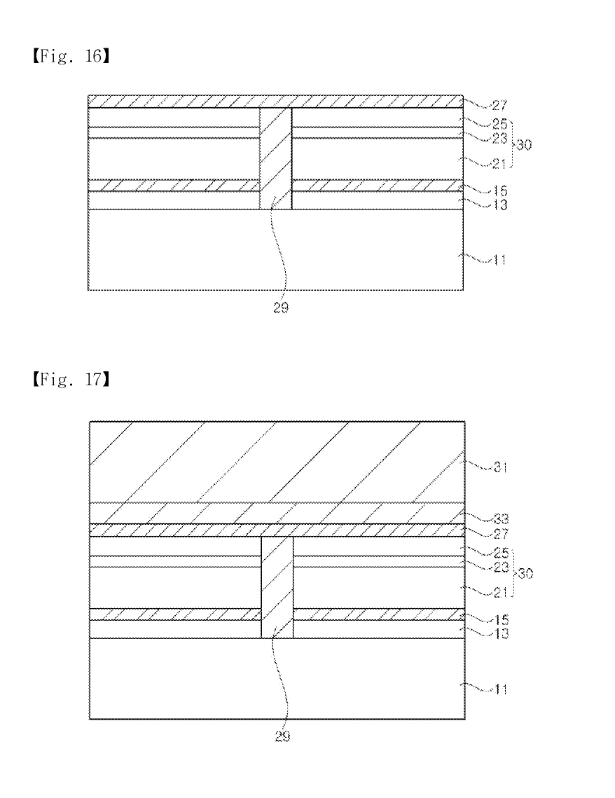

Referring to FIG. 16, a p-electrode layer 27 is formed on the semiconductor stack 30. The p-electrode layer 27 is in ohmic contact with the p-type semiconductor layer 25. The p-electrode layer 27 may include a reflective metal layer and a barrier metal layer.

In some embodiments, before the p-electrode layer 27 is formed, a filler 29 for filling the grooves 30a may be formed. The filler 29 may be formed, for example, by spin-coating a photoresist, SOG, or the like.

In other embodiments, after the p-electrode layer 27 is formed to be restricted within the range of the semiconductor stack 30, the filler 29 may be formed. That is, the p-electrode layer 27 is formed on the semiconductor stack 30 so as to expose the grooves 30a, the filler 29 may then fill the grooves defined by the semiconductor stack 30 and the p-electrode layer 27.

Referring to FIG. 17, a support substrate 31 is then attached on the p-electrode layer 27. After being fabricated separately from the semiconductor stack 30, the support substrate 31 may be bonded on the p-electrode layer 27 through a bonding metal 33. The support substrate 31 may be formed on the p-electrode layer 27 through a plating process. The support substrate 31 may be a conductive substrate, e.g., a metal or semiconductor substrate. The support substrate 31 is positioned on the semiconductor stacks 30 divided from one another, so as to combine the semiconductor stacks 30 with one another.

Referring to FIG. 18, the filler 29 is removed using a wet etching technique. The filler 29 may be removed by appropriately selecting an organic solvent such as buffer oxide echant (BOE), HF or acetone, depending on the material of the filler. For example, if the filler is formed of SOG, the BOE or HF may be used. If the filler is a photoresist, the organic solvent such as acetone may be used. As the filler 29 is removed, a passage is formed by the groove 30a between the GaN substrate 11 and the support substrate 31.

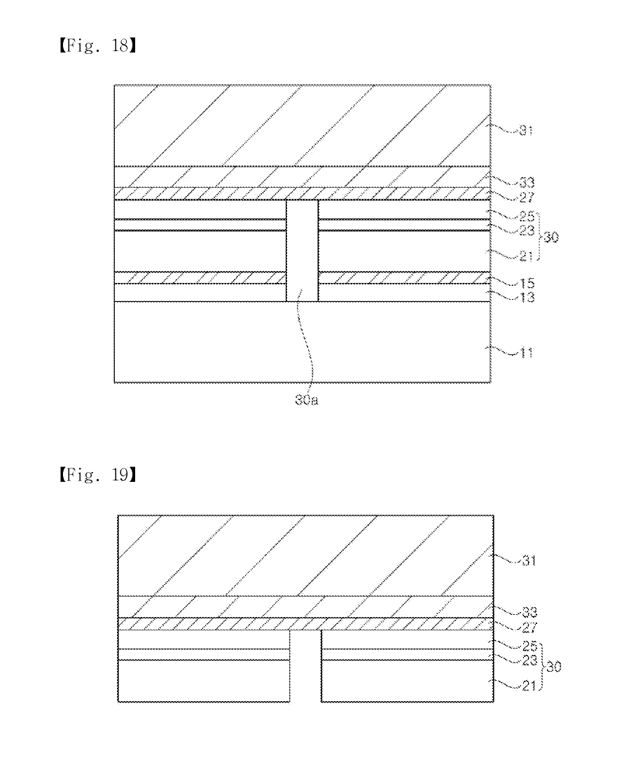

Referring to FIG. 19, the GaN substrate 11 is subsequently separated from the semiconductor stack 30, and the surface of the n-type semiconductor layer 21 is exposed. The GaN substrate 11 may be separated from the semiconductor stack 30 using the photo-enhanced chemical etching technique. FIG. 20 is a schematic view illustrating a process of separating the GaN substrate 11.

Referring to FIG. 20, after a passage is defined by the groove 30a as described with reference to FIG. 18, the entire object including the GaN substrate 11 is immersed in a bath 100 containing a KOH or NaOH solution 110. Meanwhile, an ultraviolet light is irradiated toward the GaN substrate 11 using an ultraviolet (UV) lamp 40. In this case, light of a wavelength that would be absorbed by the GaN substrate 11 among light L1 generated from the UV lamp 40 is pre-filtered using a filter 45, except for light L2 of a wavelength to be absorbed by the sacrificial layer 15. The filter 45 may be formed, for example, by growing a GaN layer 43 on a sapphire substrate 41. Thus, the GaN layer 43 blocks, in advance, the light of the wavelength that would be absorbed by the GaN substrate 11.

Accordingly, the light L2 that is transmitted through the GaN substrate 11 is irradiated onto the sacrificial layer 15 through the GaN substrate 11 in the bath 100. Side surfaces of the sacrificial layer 15 are exposed to the inner walls of the grooves 30a, and also absorb the light L2. Thus, the sacrificial layer 15 is etched by the KOH or NaOH solution 110 penetrating into the grooves 30a.

The light may be irradiated by using, instead of the UV lamp 40, a laser or LED that emits light of a specific wavelength, i.e., light of a wavelength that will be transmitted through the GaN substrate 11 and absorbed by the sacrificial layer 15.

According to this embodiment, since the grooves 30a are formed on the substrate 11, the sacrificial layer 15 is etched in an edge region as well as an inner region of the substrate 11. Thus, the GaN substrate 11 can be easily separated from the semiconductor stack 30 even when the size of the substrate 11 is relatively large.

As the GaN substrate 11 is removed, the surface of the n-type semiconductor layer 21 is exposed and then partially etched to form a roughened surface or concavo-convex pattern. The concavo-convex pattern may be formed by vapor depositing a transparent oxide layer (35 of FIG. 1) on the n-type semiconductor layer 21 and patterning the deposited transparent oxide layer. Then, an n-electrode pad 37 and a bonding pad 39 may be formed, and the semiconductor stack 30 is divided into individual LEDs, thereby resulting in the completed LED of FIG. 1.

If a conventional sapphire substrate is used as the growth substrate, the sapphire substrate can be easily separated using an interface between the substrate and the semiconductor layers, since the sapphire substrate has physical properties different from those of semiconductor layers grown on the sapphire substrate. However, If the GaN substrate 11 is used as the growth substrate, it is difficult to separate the substrate 11 using an interface between the substrate 11 and the semiconductor layers 21, 23 and 25, since the GaN substrate 11 and the semiconductor layers 21, 23 and 25 grown on the GaN substrate 11 are made of a homogeneous material.

Accordingly, in the present invention, the GaN substrate 11 is separated using the sacrificial layer 15. Thus, the GaN substrate 11 can be separated from the semiconductor stack 30 without damaging the GaN substrate 11. Since the separated GaN substrate 11 is not damaged, the GaN substrate 11 can be reused as the growth substrate.

FIG. 21 is a sectional view illustrating a miscut GaN substrate that may be used as the growth substrate in the embodiments of the present invention.

Referring to FIG. 21, the substrate 210 is a semi-polar GaN substrate having a principal surface inclined at a degree ranging from 15 to 85 degrees with respect to c-axis. The substrate 210 has miscut surfaces 210a inclined in one direction with respect to the principal surface.

A kink is formed by forming the miscut surfaces 210a. The kink provides a nuclear generation sites in the growth of a GaN-based semiconductor layer so that the semiconductor layer can be easily grown. The miscut surfaces 210a are not particularly limited thereto, and may be c-plane.

The principal surface of the substrate 210 may be a semi-polar surface such as (20-21), (20-2-1), (10-11), (10-1-1), (11-22), (11-2-2), (30-31) or (30-3-1), or a family thereof.

By growing GaN-based semiconductor layers on the substrate 210, it is possible to grow semiconductor layers having semi-polar surfaces identical to that of the substrate 210. Particularly, since spontaneous polarization and piezoelectric polarization of the GaN-based semiconductor layers are relatively smaller than those of a polar semiconductor layer, light emitting efficiency can be improved.

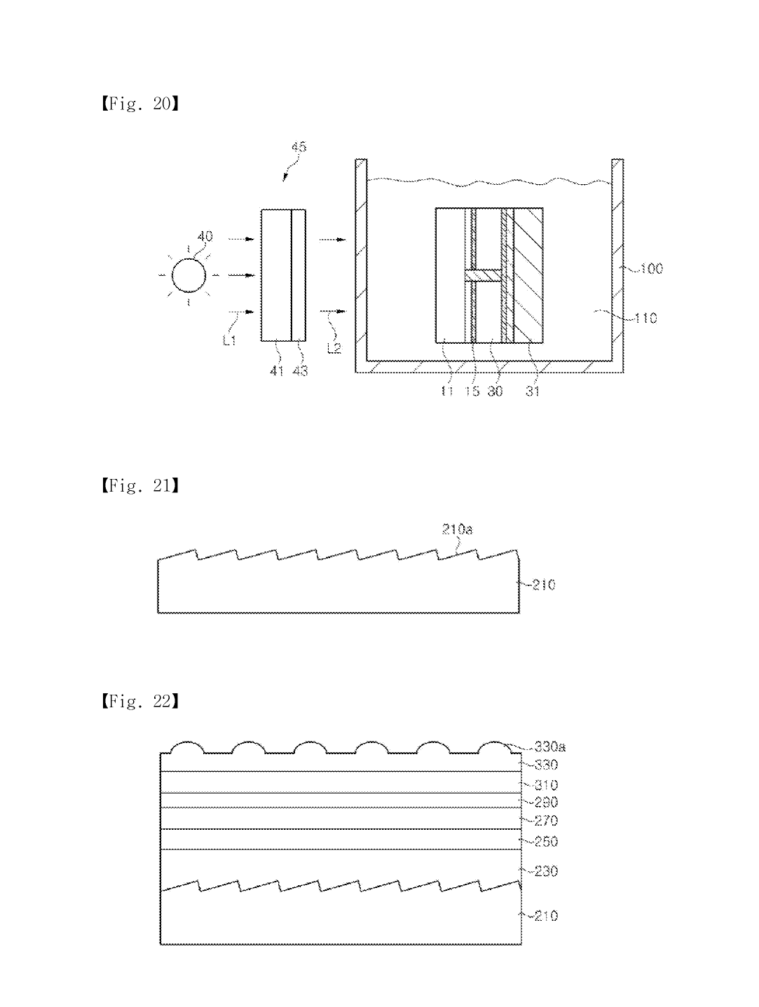

FIG. 22 is a sectional view illustrating an LED according to a further embodiment of the present invention.

Referring to FIG. 22, the LED includes a substrate 210, a buffer layer 230, a first conductive semiconductor layer 250, a superlattice layer 270, an active layer 290, a second conductive semiconductor layer 310 and a transparent oxide layer 330. The LED may further include an electrode pad (not shown) on the transparent oxide layer 330.

The substrate 210 is a substrate described with reference to FIG. 21, and therefore, the detailed description of the substrate 210 will be omitted. Here, the substrate 210 is a conductive substrate so that the substrate 210 may be used as an electrode. Alternatively, an electrode may be formed on a lower side of the substrate 210.

The buffer layer 230, the first conductive semiconductor layer 250, the superlattice layer 270, the active layer 290, the second conductive semiconductor layer 310 are grown as epitaxial layers on the substrate 210.

The epitaxial layers, particularly the active layer 290 may be grown as a semi-polar semiconductor layer by being grown on the semi-polar substrate 210. Thus, the polarization of the active layer 290 is relatively smaller than that of the polar semiconductor layer.

The buffer layer 230 is formed to improve crystallinity by reducing strain in an epitaxial layer grown on the substrate 210. The buffer layer 230 may be a GaN layer having the same composition as that of the substrate but is not necessarily limited thereto. The buffer layer 230 may be omitted.

The first conductive semiconductor layer 250 may be grown as, for example, a GaN layer doped with an n-type impurity. The superlattice layer 270 may be formed by alternately stacking GaN-based layers having different bandgaps, e.g., a GaN layer and an InGaN layer.

The active layer 290 includes a well layer having a relatively narrow bandgap so that electrons and holes can be recombined therein. The active layer 290 may have a single or multiple quantum well structure.

The second conductive semiconductor layer 310 may be grown as, for example, a GaN layer doped with a p-type impurity. Further, the second conductive semiconductor layer 310 may include an electron blocking layer.

The epitaxial layers may be grown using an MBE or MOCVD technique.

The transparent oxide layer 330 is positioned on a semiconductor stack including the first conductive semiconductor layer 250, the active layer 290 and the second conductive semiconductor layer 310. The transparent oxide layer 330 is formed for electrical current spreading. The transparent oxide layer 330 may have a concavo-convex pattern 330a on an upper surface thereof. In order to realize the electrical current spreading and to form the concavo-convex pattern 330a, the entire thickness of the transparent oxide layer 330 may be about 1 μm or more, and the thickness of the main portion of the transparent oxide layer 330 may be 0.5 μm or more.

The transparent oxide layer 330 may be formed of ITO or ZnO. For example, the transparent oxide layer 330 having the concavo-convex pattern may be formed by primarily forming a portion of the transparent oxide layer and then forming convex portions through a lift-off process.

The transparent oxide layer 330 having the concavo-convex pattern 330a enhances light extraction efficiency of light generated in the active layer 290, thereby improving light emitting efficiency of the LED.

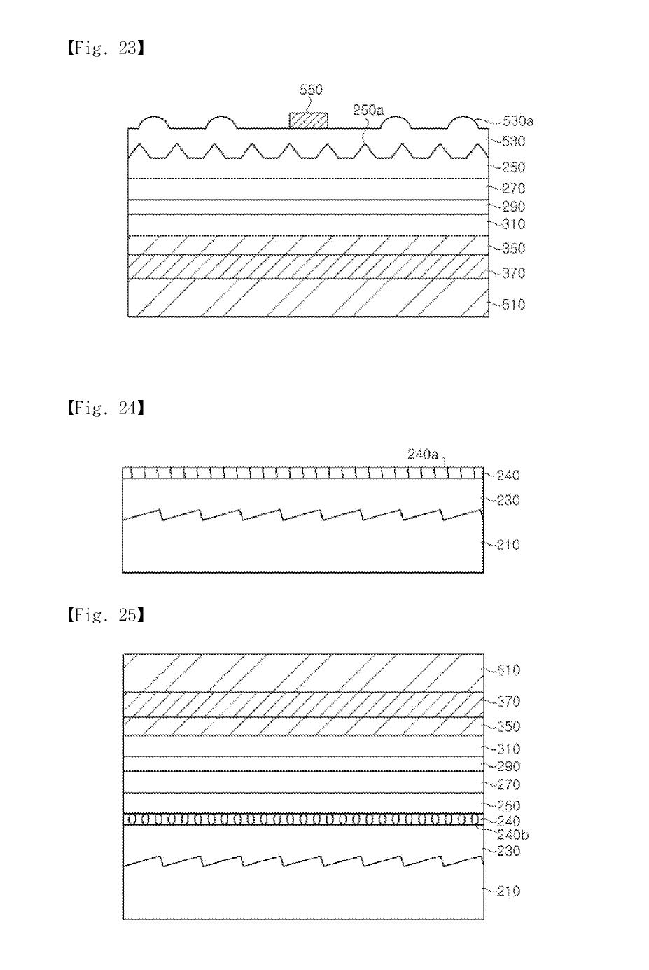

FIG. 23 is a sectional view illustrating an LED according to a further embodiment of the present invention.

Referring to FIG. 23, the LED according to this embodiment includes a substrate 510, a bonding metal 370, a reflective layer 350, a first conductive semiconductor layer 250, a superlattice layer 270, an active layer 290, a second conductive semiconductor layer 310 and a transparent oxide layer 330. The LED may further include an electrode pad 550 formed on the transparent oxide layer 530.

The substrate 510 is a conductive substrate, e.g., a metal substrate. The substrate 510 is distinguished from a growth substrate, and is a secondary substrate attached on a semiconductor stack which has already been grown.

The bonding metal 370 is used to couple the substrate 510 and the semiconductor stack to each other, and may be, for example, AuSn. The reflective layer 350 may be formed to reflect light that is emitted from the active layer 290 and travels toward the substrate 510, and may be formed of Ag and include a barrier metal layer for preventing diffusion of Ag.

Meanwhile, the first conductive semiconductor layer 250, the superlattice layer 270, the active layer 290 and the second conductive semiconductor layer 310 are the same components as the respective layers of the semiconductor stack described with reference to FIG. 22, and are designated by like reference numerals. Thus, each layer, particularly the active layer 290 is formed as a semi-polar semiconductor layer. However, in this embodiment, the semiconductor stack has an inverted structure as compared with the embodiment of FIG. 22. The first conductive semiconductor layer 250 may have a concavo-convex pattern 250a on an upper surface thereof.

The transparent oxide layer 530 is positioned on the first conductive semiconductor layer 250, and may have a concavo-convex pattern 530a. The transparent oxide layer 530 is similar to the transparent oxide layer 330 described above, and therefore, the detailed description of the transparent oxide layer 530 will be omitted.

The electrode pad 550 is positioned on the transparent oxide layer 530. The electrode pad 550 is generally provided to bond a bonding wire thereto.

FIGS. 24 to 26 are sectional views illustrating a method of fabricating the LED of FIG. 23.

Referring to FIG. 24, a miscut semi-polar GaN substrate 210 having a principal surface inclined at an angle ranging from 15 to 85 degrees with respect to c-plane is first prepared. The substrate 210 is the same as the substrate 210 described with reference to FIG. 21, and therefore, the detailed description of the substrate 210 will be omitted.

A buffer layer 230 is grown on the substrate 210. The buffer layer 230 may be grown as a nitride layer undoped with impurities, e.g., a GaN layer. Here, the buffer layer 230 is used as a layer for growing an epitaxial layer thereon, and is also required to separate the substrate 210 therefrom.

A nitride layer 240 having a porous structure with pores 240a is formed on the buffer layer 230. For example, the nitride layer 240 having the porous structure may be formed by growing a GaN layer doped with Si at a concentration ranging from 1×10¹⁸/cm³ to 10×10¹⁹/cm³ and then etching the GaN layer through electrochemical etching. The electrochemical etching may be performed by immersing the substrate 210 having the nitride layer doped with the impurity and a Pt electrode in, for example, an oxalic acid solution (0.3M oxalic acid) at about 10° C.; and connecting positive and negative electrodes to the nitride layer and the Pt electrode, respectively, to apply a DC voltage (25-60V) thereto.

The porous structure, as shown in FIG. 24, may have nanoscale rod-shaped pores 240a that extend from the surface of the nitride layer 240 to the buffer layer 230.

Referring to FIG. 25, a semiconductor stack is formed by growing epitaxial layers, e.g., a first conductive semiconductor layer 250, a superlattice layer 270, an active layer 290 and a second conductive semiconductor layer 310, on the nitride layer 240 with the porous structure. These epitaxial layers are the same as those described with reference to FIG. 22, and therefore, their detailed descriptions will be omitted.

Meanwhile, while the epitaxial layers are grown at a relatively high temperature, the pores 240a are also grown, resulting in voids 240b formed within the nitride layer 240. In addition, a thermal process at about 1000° C. may be additionally performed to further increase the size of the voids 240b within the nitride layer 240.

Subsequently, a reflective layer 350 is formed on the semiconductor stack. The reflective layer 350 may be formed of a reflective metal such as Ag, and may include a barrier metal layer for preventing Ag from being diffused. Then, a substrate 510 is attached on the reflective layer 350 with a bonding metal 370 interposed therebetween. The bonding metal 370 may be, for example, AuSn, and the substrate 510 may be a metal substrate.

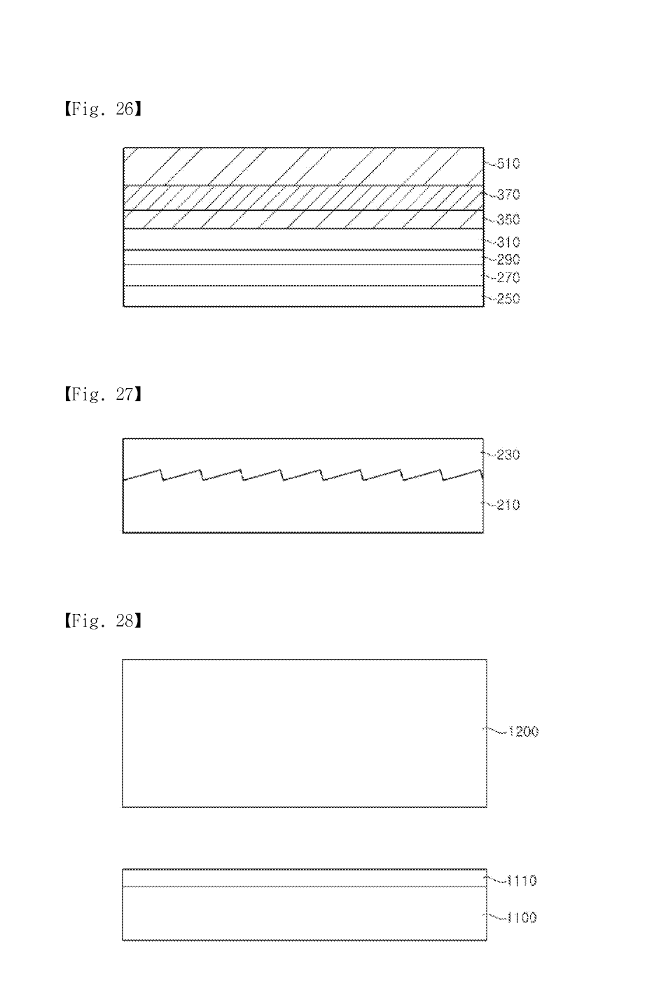

Referring to FIG. 26, after the substrate 510 is attached, the semi-polar GaN substrate 210 is removed using the nitride layer 240 with the voids 240b formed therein. For example, the semi-polar GaN substrate 210 may be separated by etching the nitride layer 240 using a chemical etching technique. Alternatively, the semi-polar GaN substrate 210 may be separated by applying a mechanical force thereto.

Then, a concavo-convex pattern (250a of FIG. 23) may be formed by patterning an exposed surface of the semiconductor stack, e.g., a surface of the first conductive semiconductor layer 250. The exposed surface of the semiconductor stack has a relatively rough surface due to the voids 240b. The concavo-convex pattern 250a may be formed using a dry etch after chemically etching or mechanically polishing an upper portion having the rough surface. Alternatively, the concavo-convex pattern 250a may be additionally formed while the rough surface remains.

Then, a transparent oxide layer 530 is formed on the first conductive semiconductor layer 250. The transparent oxide layer 530 may be formed to have a concavo-convex pattern 530a as described with reference to FIG. 22, and its detailed description will be omitted.

Subsequently, an electrode pad 550 is formed on the transparent oxide layer 530, and accordingly, an LED with a vertical structure is provided.

FIG. 27 is a sectional view illustrating the semi-polar GaN substrate separated from FIG. 26.

Referring to FIG. 27, the semi-polar GaN substrate 210 together with the buffer layer 230 is separated from the semiconductor stack. The semi-polar GaN substrate 210 maintains its original configuration, and thus, can be reused as a growth substrate by being miscut again.

As the semi-polar GaN substrate 210 is reused, the fabrication cost of the semi-polar GaN substrate 210 may be reduced, and accordingly, the fabrication cost of the LED may be reduced.

FIGS. 28 to 30 are sectional views illustrating a method of fabricating a semiconductor device according to a still further embodiment of the present invention.

Referring to FIG. 28, the method according to this embodiment includes first preparing a support substrate 1100 and a bulk substrate 1200.

The support substrate 1100 may be any substrate to which the bulk substrate 1200 can be attached. However, the support substrate 1100 may be preferably a Si substrate, sapphire substrate, MN substrate, Ge substrate or SiC substrate, in consideration of the thermal expansion coefficient and the like of the bulk substrate 1200.

The bulk substrate 1200 may be an (Al, Ga, In)N based Group III nitride semiconductor substrate, i.e., a nitride semiconductor single crystal substrate. The bulk substrate 1200 may include GaN, and preferably may be a GaN single crystal substrate.

The bulk substrate 1200 may be a p-type or n-type GaN single crystal substrate doped with impurities.

The bulk substrate 1200 may be a GaN single crystal substrate fabricated using an HVPE technique, Na flux technique, ammonothermal technique, or the like. The bulk substrate 1200 may have a thickness of at least 100 μm.

Subsequently, a joining layer 1110 is formed on one surface of the support substrate 1100. The joining layer 1110 may be made of an oxide including at least one of Zn, Si, Ga and Al. Alternatively, the joining layer 1110 may be made of a nitride including at least one of Si, Ga and Al.

The joining layer 1110 may be formed using a CVD technique, E-beam technique, chemical solution technique, or the like. The joining layer 1110 may be formed as a single layer or multilayer. If the joining layer 1110 is formed as a multilayer, respective sub-layers of the multilayer may be made of the same kind of material but have different compositions. Alternatively, the sub-layers may be made of different kinds of materials.

Although not shown in this figure, a metallic intermediate layer (not shown) may be formed on the joining layer 1110. The metallic intermediate layer (not shown) may include a material having a melting point of 1000° C. or more.

In this case, a concavo-convex pattern 1120 may be provided on one surface of the support substrate 1100, as shown in FIG. 31. The concavo-convex pattern 1120 may be formed in the shape of stripes.

The concavo-convex pattern 1120 may serve to alleviate stress that could be generated after the support substrate 1100 and the bulk substrate 1200 are joined together. The concavo-convex pattern 1120 may be used as a penetration passage of an etching solution when the support substrate 1100 is separated.

Referring to FIG. 29, the bulk substrate 1200 is joined on the one surface of the support substrate 1100. The support substrate 1100 and the bulk substrate 1200 may be joined together under high temperature and high pressure.

If the metallic intermediate layer (not shown) is provided on the joining layer 1110, the metallic intermediate layer (not shown) is formed in the shape of islands. The metallic intermediate layer (not shown) is deformed from a layered shape into an island shape by being melted or reflowed at a temperature at which the support substrate 1100 and the bulk substrate 1200 are joined together, thereby contributing to enhance the joining force between the support substrate 1100 and the bulk substrate 1200.

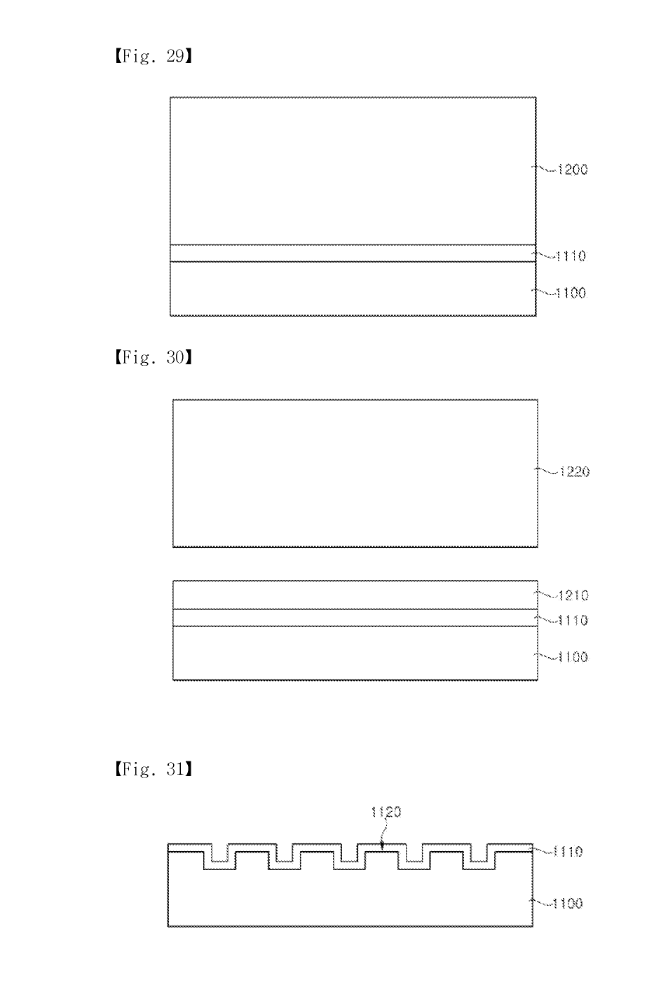

Referring to FIG. 30, the bulk substrate 1200 is cut and separated at a region corresponding to a predetermined thickness from the joining layer 1110, so that a seed layer 1210 attached to the support substrate 1100 by the joining layer 1110 can be formed together with the separated bulk substrate 1220.

That is, the seed layer 1210 is formed by cutting the bulk substrate 1200 to the predetermined thickness and separating it. If the process described above is repeated using the separated bulk substrate 1220, a plurality of support substrates 1100 each of which has the seed layer 1210 attached thereto may be formed.

Through the process described above, a semiconductor device substrate capable of allowing formation of a semiconductor device can be formed. In this case, the seed layer 1210 may be non-polar or semi-polar. Particularly, the seed layer 1210 may be provided as an expensive non-polar or semi-polar layer, regardless of the support substrate 1100. That is, since the seed layer 1210 is formed by being cut and separated from the bulk substrate 1200, the seed layer 1210 can be obtained with a desired configuration by controlling the direction in which the bulk substrate 1200 is grown or cut.

FIGS. 32 and 33 are sectional views illustrating a method of fabricating a semiconductor device according to a still further embodiment of the present invention.

Referring to FIG. 32, the method according to this embodiment, e.g., a method of fabricating an LED device, includes first forming a semiconductor device substrate having a seed layer 1210 formed on a support substrate 1100, as described with reference to FIGS. 28 to 30.

Subsequently, a process of planarizing one surface of the separated seed layer 1210 may be performed. This is because the one surface of the seed layer 1210 may be a very rough separated surface if the seed layer 1210 is cut and separated from the bulk substrate 1200. It will be apparent that the planarization process may be omitted if the seed layer 1210 is formed through a growth technique or if the one surface of the seed layer 1210 is not rough. Alternatively, the planarization process may be omitted as requested.

Then, a plurality of semiconductor layers including at least a first conductive semiconductor layer 1310, an active layer 1320 and a second conductive semiconductor layer 1330 are formed on the seed layer 1210 of the semiconductor device substrate.

The plurality of semiconductor layers may further include a superlattice layer (not shown) or an electron blocking layer (not shown). In this case, the other layers except for the active layer 1320 may be omitted in the plurality of semiconductor layers.

The first conductive semiconductor layer 1310 may be a Group III-N based compound semiconductor layer doped with a first conducive impurity, e.g., an n-type impurity. For example, the first conductive semiconductor layer 1310 may be an (Al, Ga, In)N based Group III nitride semiconductor layer. The first conductive semiconductor layer 1310 may be a GaN layer doped with an n-type impurity, i.e., an n-GaN layer. The first conductive semiconductor layer 1310 may be formed as a single layer or multilayer. For example, when the first conductive semiconductor layer 1310 is formed as a multilayer, the first conductive semiconductor layer 1310 may be made to have a superlattice structure.

The active layer 1320 may be a Group III-N based compound semiconductor layer, e.g., an (Al, Ga, In)N semiconductor layer. The active layer 1320 may be formed as a single layer or multilayer and emit light of at least a predetermined wavelength. The active layer 1320 may have a single quantum well structure including one well layer (not shown), or may have a multiple quantum well structure in which well layers (not shown) and barrier layers (not shown) are alternately and repetitively stacked. At this time, one or both of the well layers (not shown) and the barrier layers (not show) may be made to have a superlattice structure.

The second conductive semiconductor layer 1330 may be a Group III-N based compound semiconductor layer doped with a second conductive impurity, e.g., a p-type impurity. For example, the second conductive semiconductor layer 1330 may be an (Al, Ga, In)N based Group III nitride semiconductor layer. The second conductive semiconductor layer 1330 may be a GaN layer doped with a p-type impurity, i.e., a p-GaN layer. The second conductive semiconductor layer 1330 may be formed as a single layer or multilayer. For example, the second conductive semiconductor layer 1330 may include a superlattice structure.

The superlattice layer (not shown) may be provided between the first conductive semiconductor layer 1310 and the active layer 1320. The superlattice layer (not shown) may have a structure in which a plurality of Group III-N based compound semiconductor layers, e.g., (Al, Ga, In)N semiconductor layers are stacked. For example, the superlattice layer (not shown) may have a structure in which InN layers and InGaN layers are repetitively stacked. The superlattice layer (not shown) is formed before the active layer 1320 is formed, so that a dislocation or defect is prevented from being transferred to the active layer 1320. Thus, the superlattice layer (not shown) can serve to reduce the formation of the dislocation or defect in the active layer 1320 and to allow the active layer 1320 to have excellent crystallinity.

The electron blocking layer (not shown) may be provided between the active layer 1320 and the second conductive semiconductor layer 1330. The electron blocking layer (not shown) may be provided to improve recombination efficiency of electrons and holes. The electron blocking layer (not shown) may be made of a material having a relatively wide bandgap. The electron blocking layer (not shown) may be made of an (Al, In, Ga)N based Group III nitride semiconductor, and may be a p-AlGaN layer doped with Mg.

In this case, the plurality of semiconductor layers are grown from the seed layer 1210, so that the semiconductor layers can be grown while taking over intact characteristics of the seed layer 1210.

That is, If the seed layer 1210 is non-polar, the plurality of semiconductor layers are also grown to be non-polar. Alternatively, if the seed layer 1210 is semi-polar, the plurality of semiconductor layer are also grown to be semi-polar. If the seed layer 1210 is a c-plane, a-plane or m-plane semiconductor layer, the plurality of semiconductor layers are also grown to be grown c-plane, a-plane or m-plane semiconductor layers.

Referring to FIG. 33, the plurality of semiconductor layers are patterned to form a semiconductor stack 1300 in which a portion of the first conductive semiconductor layer 1310 is exposed.

Subsequently, a transparent conductive oxide (TCO) layer 1400 is formed on the second conductive semiconductor layer 1330 of the semiconductor stack 1300.

Then, a first electrode 1510 is formed on the exposed first conductive semiconductor layer 1310, and a second electrode 1520 is formed on the TCO layer 1400, thereby fabricating an LED device.

In this case, although it has been described that the TCO layer 1400 is formed after the semiconductor stack 1300 is formed, it is possible to perform a process of forming the semiconductor stack 1300 by first forming the TCO layer 1400 and then exposing a portion of the first conductive semiconductor layer 1310 through etching of a portion of the TCO layer 1400 and a portion of the plurality of semiconductor layers.

The TCO layer 1400 may include a transparent metal oxide such as ITO or ZnO, and the thickness of the TCO layer 1400 may be a few to a few tens of micrometers (μm).

In this case, the TCO layer 1400 may have concavo-convex portions 1410 formed on a surface thereof.

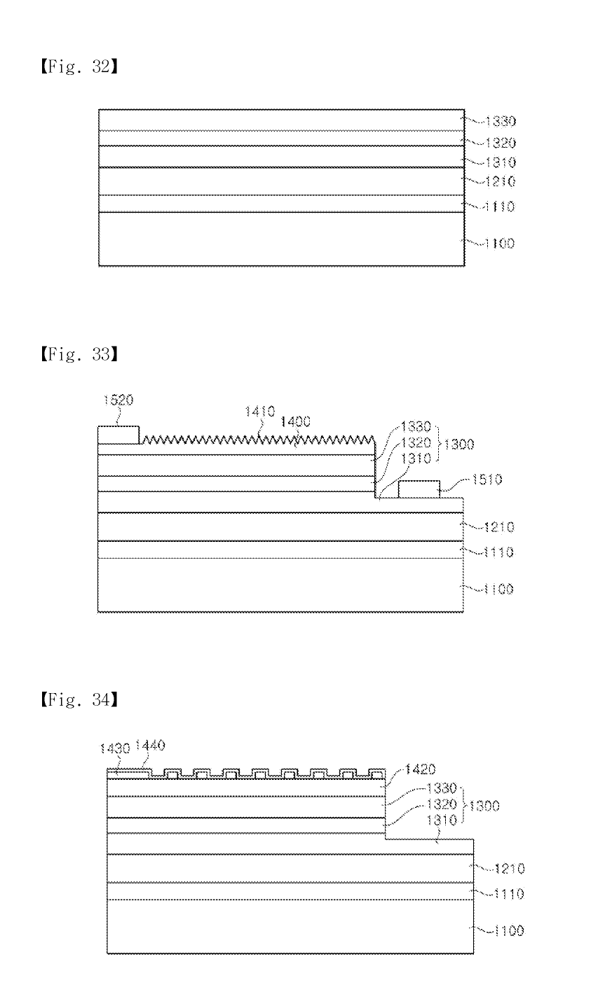

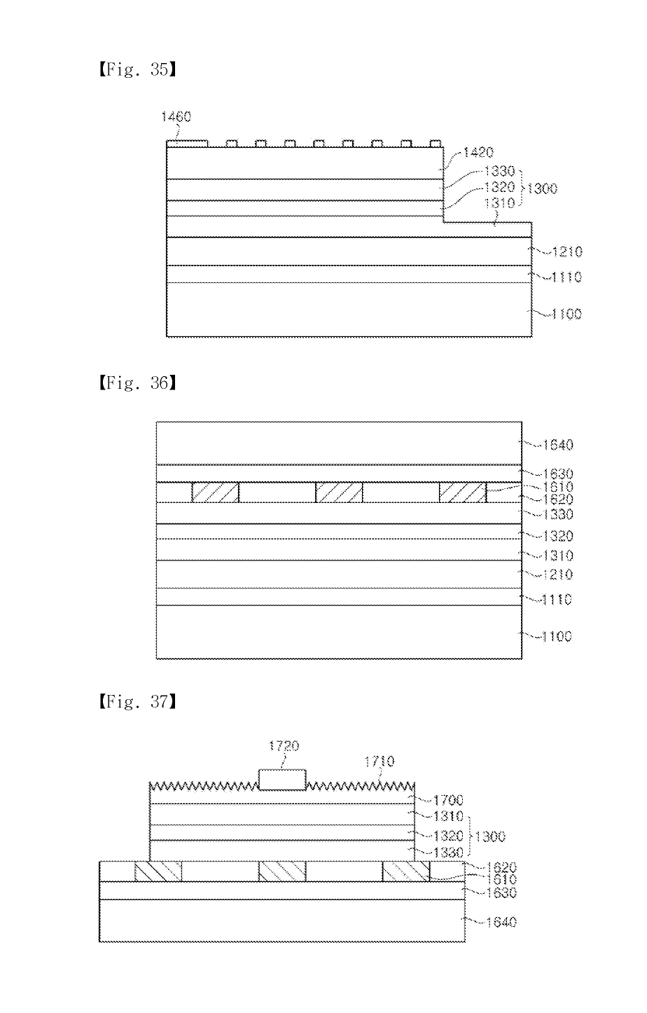

The TCO layer 1400 having the concavo-convex portions 1410 formed on the surface thereof may be formed using methods shown in FIGS. 34 and 35.

That is, as shown in FIG. 34, a first TCO layer 1420 with a predetermined thickness is formed on the semiconductor stack 1300, and a photoresist pattern 1430 is formed on the first TCO layer 1420.

Subsequently, a second TCO layer 1440 with a predetermined thickness is formed on the first TCO layer 1420 having the photoresist pattern 1430 formed thereon, and portions of the photoresist pattern 1430 and the second TCO layer 1440 formed on the photoresist pattern 1430 are removed using a lift-off technique, so that the TCO layer 1400 having the concavo-convex portions 1410 formed on the surface thereof may be formed.

As shown in FIG. 35, a third TCO layer 1450 with a predetermined thickness is formed on the semiconductor stack 1300, and a photoresist pattern 1460 is formed on the third TCO layer 1450. Subsequently, a surface of the third TCO layer 1450 is wet-etched to a predetermined depth using the photoresist pattern 1460 as a mask, so that the TCO layer 1400 having the concavo-convex portions 1410 formed on the surface thereof may be formed. In this case, the wet etching allows the concavo-convex portions 1410 to be etched so that a crystal surface is exposed by selectively etching the surface of the TCO layer 1400 along the crystal surface. Therefore, the concavo-convex portions 1410 may be formed in a polypyramid in shape.

FIGS. 36 and 37 are sectional views illustrating a method of fabricating a semiconductor device according to a still further embodiment of the present invention.

Referring to FIG. 36, the method according to this embodiment, e.g., a method of fabricating an LED device, includes first forming a semiconductor device substrate having a seed layer 1210 formed on a support substrate 1100, as described with reference to FIGS. 28 to 30.

Subsequently, similarly to the method described with reference to FIG. 32, a process of planarizing one surface of the separated seed layer 1210 is performed, and a plurality of semiconductor layers including at least a first conductive semiconductor layer 1310, an active layer 1320 and a second conductive semiconductor layer 1330 are formed on the seed layer 1210 of the semiconductor device substrate. In this case, the plurality of semiconductor layers may further include a superlattice layer (not shown) or an electron blocking layer (not shown). The other layers except for the active layer 1320 may be omitted in the plurality of semiconductor layers.

Subsequently, an etch stop pattern 1610 is formed on the second conductive semiconductor layer 1330.

The etch stop pattern 1610 may be formed as an insulation layer such as silicon oxide or silicon nitride. The etch stop pattern 1610 may serve to notify when the etching is completed upon patterning the plurality of semiconductor layers. In addition, the etch stop pattern 1610 is positioned directly below an electrode pad 1720 as will be described later, so that the etch stop pattern 1610 may serve to allow the electrical current injected from the electrode pad 1720 to be equally spread, thereby causing the electrical current to be generally uniformly supplied to the semiconductor stack 1300, particularly the entire active layer 1320.

Meanwhile, an ohmic reflective pattern 1620 may be formed on the second conductive semiconductor layer 1330. The ohmic reflective pattern 1620 may be a pattern that is in ohmic contact with the second conductive semiconductor layer 1330 and also acts as a reflective layer for reflecting light emitted from the active layer 1320.

In this case, the etch stop pattern 1610 has open regions, and the ohmic reflective pattern 1620 may be filled in the open regions of the etch stop pattern 1610. That is, the etch stop pattern 1610 and the ohmic reflective pattern 1620 may form one layer.

Subsequently, a metal bonding layer 1630 may be formed on the etch stop pattern 1610 or the ohmic reflective pattern 1620. The metal bonding layer 1630 serves to bond the etch stop pattern 1610 or the ohmic reflective pattern 1620 to a metal substrate 1640 to be formed later. The metal bonding layer 1630 may be made of a conductive material.

Subsequently, the metal substrate 1640 is formed.

The metal substrate 1640 may be formed by preparing a conductive metal substrate and then bonding the conductive metal substrate by using the metal bonding layer 1630.

Meanwhile, the metal substrate 1640 may be formed directly on the second conductive semiconductor layer 1330. That is, any of the etch stop pattern 1610, the ohmic reflective pattern 1620 and the metal bonding layer 1630, which would be formed on the second conductive semiconductor layer 1330, is omitted, and the metal substrate 1640 may be formed. In this case, the metal substrate 1640 may be formed using a plating method, vapor deposition method, chemical solution method or the like.

In this case, the metal substrate 1640 may be made of a conductive material, and may preferably include Cu/W or Cu/Mo.

Referring to FIG. 37, after the metal substrate 1640 is formed, the support substrate 1100 is removed.

The removal of the support substrate 1100 may be made through decomposition of the joining layer 1110. That is, if the joining layer 1110 is formed of a nitride or oxide as described above, the joining layer 1110 can be decomposed using a solution capable of decomposing the joining layer 1110, i.e., a HF, buffer oxide etchant (BOE) or nitric acid solution.

If the concavo-convex pattern 1120 is provided on the one surface of the support substrate 1100 as shown in FIG. 31, the solution capable of decomposing the joining layer 1110 can be more easily penetrated through the concavo-convex pattern 1120, so that the support substrate 1100 can be easily decomposed and removed.

The support substrate 1100 may be separated using a laser. That is, the support substrate 1100 may be separated from the seed layer 1210 by irradiating the joining layer 1110 with the laser.

Then, a process of removing the seed layer 1210 may be performed.

However, a next process may be performed without removing the seed layer 1210. If the seed layer 1210 is not removed, the next process may be performed after the process of planarizing the surface of the seed layer 1210 is performed.

Only a portion of the seed layer 1210 may be removed using a wet or dry etching process so that the other portion of the seed layer 1210 may remain.

Subsequently, the semiconductor stack 1300 may be formed by patterning the plurality of semiconductor layers. In this case, the plurality of semiconductor layers may be etched under the condition that the etching stops when the etch stop pattern 1610 is exposed.

Meanwhile, although it has been described in this embodiment that the process of patterning the plurality of semiconductor layers is performed between the process of removing the seed layer 1210 and the process of forming a TCO layer 1700 as will be described later, the process of patterning the plurality of semiconductor layers may be performed any time before an electrode pad 1720, which will be described later, is formed after the support substrate 1100 is removed.

Subsequently, the TCO layer 1700 may be formed on the surface exposed by separating the support substrate 1100, e.g., the surface of the seed layer 1210 or the surface of the first conductive semiconductor layer 1310.

In this case, the TCO layer 1700 may have a concavo-convex portions 1710 formed on a surface thereof. Here, the concavo-convex portions 1710 of the TCO layer 1700 may be formed using the same method as the TCO layer 1400 having the concavo-convex portions 1410 formed on the surface thereof as described with reference to FIGS. 34 and 35, and thus, a detailed description thereof will be omitted.

Subsequently, the electrode pad 1720 is formed on the TCO layer 1700 to form an LED device.

The method may further include a process of forming a passivation layer (not shown) for protecting the semiconductor stack 1300 including the TCO layer 1700 before the electrode pad 1720 is formed.

In this case, the concavo-convex portions 1710 may not be formed in a predetermined region of the TCO layer 1700 where the electrode pad 1720 is formed. The etch stop pattern 1610 may be formed directly below the electrode pad 1720.

The size of the electrode pad 1720 may be smaller than that of the etch stop pattern 1610 positioned directly below the electrode pad 1720. That is, the size of the etch stop pattern 1610 positioned directly below the electrode pad 1720 may be larger than that of the electrode pad 1720. This may allow the current supplied to the electrode pad 1720 to uniformly flow through the semiconductor stack 1300 positioned between the electrode pad 1720 and the etch stop pattern 1610, particularly through the active layer 1320.

Although the various embodiments and features of the present invention have been described above, the present invention is not limited to the aforementioned embodiments and features. Various modifications can be made thereto without departing from the spirit and scope of the invention.

1. A light emitting diode (LED), comprising:
a substrate;
a semiconductor stack disposed on the substrate and comprising a gallium nitride (GaN)-based p-type semiconductor layer, a GaN-based active layer, and a GaN-based n-type semiconductor layer;
a p-electrode layer in ohmic contact with the p-type semiconductor layer and disposed between the substrate and the semiconductor stack; and
a transparent oxide layer disposed on the semiconductor stack and comprising a first surface comprising a concavo-convex pattern,
wherein the semiconductor stack has a dislocation density of 5×10⁶/cm² or less.

2. (canceled)

3. The LED of claim 1, further comprising an n-electrode pad disposed on the first surface of the transparent oxide layer and electrically connected to the n-type semiconductor layer.

4. The LED of claim 1, further comprising:
an n-electrode layer disposed between the substrate and the semiconductor stack and connected to the n-type semiconductor layer through a through-hole penetrating the p-type semiconductor layer and the active layer; and
an insulation layer insulating the p-electrode layer and the n-electrode layer from each other.

5. The LED of claim 4, further comprising a p-electrode pad disposed on the p-electrode layer.

6. An LED, comprising:
a substrate;
a semiconductor stack disposed on the substrate and comprising a GaN-based p-type semiconductor layer, a GaN-based active layer, and a GaN-based n-type semiconductor layer;
a p-electrode layer in ohmic contact with the p-type semiconductor layer and disposed between the substrate and the semiconductor stack;
an n-electrode layer disposed between the substrate and the semiconductor stack and connected to the n-type semiconductor layer through a through-hole penetrating the p-type semiconductor layer and the active layer; and
an insulation layer insulating the p-electrode layer and the n-electrode layer from each other,
wherein the semiconductor stack has a dislocation density of 5×10⁶/cm² or less.

7. The LED of claim 6, further comprising a bonding pad,
wherein the substrate is disposed between the bonding pad and the semiconductor stack.

8. The LED of claim 6, further comprising a p-electrode pad disposed on the p-electrode layer.

9. The LED of claim 6, wherein the insulation layer insulates the n-electrode layer from the p-type semiconductor layer and the active layer within the through-hole.

10. The LED of claim 9, further comprising a transparent oxide layer disposed on the semiconductor stack and comprising a first surface comprising a concavo-convex pattern.

11. A method of fabricating an LED, the method comprising:
forming a first GaN layer, a sacrificial layer, and a second GaN layer on a GaN substrate, the sacrificial layer having a bandgap narrower than bandgaps of the GaN layers;
forming a groove penetrating the second GaN layer and the sacrificial layer;
growing GaN-based semiconductor layers on the second GaN layer to form a semiconductor stack;
forming a substrate on the semiconductor stack; and
etching the sacrificial layer to remove the GaN substrate from the semiconductor stack.

12. The method of claim 11, wherein the sacrificial layer comprises InGaN.

13. The method of claim 11, wherein the etching of the sacrificial layer comprises using a photo-enhanced chemical etching technique.

14. The method of claim 13, wherein the etching of the sacrificial layer comprises irradiating the sacrificial layer with light through the GaN substrate in a KOH or NaOH solution.

15. The method of claim 11, further comprising forming a transparent oxide layer on the n-type semiconductor layer, after removing the GaN substrate,
wherein the transparent oxide layer comprises a first layer comprising a concavo-convex pattern.

16. The method of claim 11, further comprising forming a p-electrode layer in ohmic contact with the semiconductor stack, before forming the substrate,
wherein:
the semiconductor stack comprises a GaN-based n-type semiconductor layer, a GaN-based active layer, and a GaN-based p-type semiconductor layer; and
the p-electrode layer is in ohmic contact with the p-type semiconductor layer.

17. The method of claim 16, further comprising, before forming the support substrate:
forming a through-hole penetrating the p-type semiconductor layer and the active layer;
forming an insulation layer covering an inner wall of the through-hole and the p-electrode layer; and
forming an n-electrode layer electrically connected to the n-type semiconductor layer, through the through-hole.

18. The method of claim 17, further comprising, after removing the GaN substrate:
removing a portion of the semiconductor stack, to expose the p-electrode layer; and
forming a p-electrode pad on the p-electrode layer.

19. The method of claim 11, wherein the groove comprises a mesh-shaped or stripe-shaped grooves.

20. The method of claim 11, further comprising:
forming a bonding pad on an opposite side of the substrate from the semiconductor stack.

21. A method of fabricating an LED, the method comprising:
forming a GaN layer and a sacrificial layer on a GaN substrate, the sacrificial layer comprising a GaN-based semiconductor having a bandgap narrower than the bandgap of the GaN layer;
growing GaN-based semiconductor layers on the sacrificial layer to form a semiconductor stack;
forming a groove penetrating the semiconductor stack and the sacrificial layer;
forming a substrate on the semiconductor stack; and
etching the sacrificial layer to separate the GaN substrate from the semiconductor stack.

22. (canceled)
